(19) United States
(12) Patent Application Publication
(10) Pub. No.: US 2026/0068089 A1
(43) Pub. Date: Mar. 5, 2026

(54) LIQUID COOLING WATER SEPARATOR AND LIQUID COOLING DEVICE FOR SERVERS

(71) Applicants: SQ TECHNOLOGY (SHANGHAI) CORPORATION, Shanghai (CN); INVENTEC CORPORATION, Taipei (TW)

(72) Inventors: Xiaogang Lu, Shanghai (CN); Hong-Chou Lin, Taipei (TW); Yu-Fan Chen, Taipei (TW)

(21) Appl. No.: 18/981,692

(22) Filed: Dec. 16, 2024

(30) Foreign Application Priority Data
Aug. 30, 2024 (CN) 202411215759.1

(51) Int. Cl. H05K 7/20

(52) U.S. Cl. CPC H05K 7/20272; H05K 7/20781

(57) ABSTRACT

A liquid cooling water separator includes: a liquid inlet main body arranged transversely, wherein a plurality of output ports are provided on one side of the liquid inlet main body, a liquid inlet connecting pipe is provided on another side of the liquid inlet main body, the liquid inlet connecting pipe is in communication with the output ports; a liquid inlet pipe arranged transversely, wherein a plurality of input ports are provided on one side of the liquid return main body, a liquid return connecting pipe is provided on another side of the liquid return main body, the liquid return connecting pipe is in communication with the input ports; a liquid inlet pipe, an output end of the liquid inlet pipe being connected to the liquid inlet connecting pipe; and a liquid return pipe, an input end of the liquid return pipe being connected to the liquid return connecting pipe.

### CROSS-REFERENCE TO RELATED APPLICATIONS

This application claims priority of Chinese Patent Application No. 2024112157591, filed on Aug. 30, 2024, entitled “LIQUID COOLING WATER SEPARATOR AND LIQUID COOLING DEVICE FOR SERVERS”, The entire content of which is incorporated herein by reference in its entirety. cl TECHNICAL FIELD

The present disclosure relates to relates to the technical field of liquid cooling device, and in particular to a liquid cooling water separator and a liquid cooling device for servers.

### BACKGROUND

With the development of servers, the computing performance of the server has been greatly improved, but at the same time, the overall power consumption and heat generation of the server have been increased, which brings great challenges to the cooling system of the server.

The server can significantly improve the heat dissipation effect by using liquid cooling technology with more outstanding heat conduction capability. The most common liquid cooling system is a water-cooling heat dissipation system. The water-cooling heat dissipation system supplies cooling water into a liquid cooling water separator through a cooling liquid distribution assembly, and the liquid cooling water separator inputs the cooling water into a single server for heat exchange. However, the conventional liquid cooling water separator is vertically arranged, the blade servers are placed vertically, and are arranged horizontally. Therefore, ports of multiple blade servers arranged horizontally cannot be directly connected to the liquid cooling water separator vertically arranged, and need to be connected to the cooling water separator through connecting pipes, so that the mounting workload is increased, and the mounting steps are complicated and the use is inconvenient.

### SUMMARY

Accordingly, it is necessary to provide a liquid cooling water separator and a liquid cooling device for servers to address a problem that the mounting steps of the liquid cooling water separator are complicated and the use thereof is inconvenient.

According to a first aspect, a liquid cooling water separator is provided, including:

a liquid inlet main body arranged transversely, wherein a plurality of output ports are provided on one side of the liquid inlet main body, a liquid inlet connecting pipe is provided on another side of the liquid inlet main body, the liquid inlet connecting pipe is in communication with the plurality of output ports, and the output ports are configured to be connected to liquid inlet ports of devices to be cooled;

a liquid return main body arranged transversely, wherein a plurality of input ports are provided on one side of the liquid return main body, a liquid return connecting pipe is provided on another side of the liquid return main body, the liquid return connecting pipe is in communication with the plurality of input ports, and the input ports are configured to be connected to liquid outlet ports of the devices to be cooled;

a liquid inlet pipe, an output end of the liquid inlet pipe being connected to the liquid inlet connecting pipe, and an input end of the liquid inlet pipe being configured to be input with cooling water; and

a liquid return pipe, an input end of the liquid return pipe being connected to the liquid return connecting pipe, and an output end of the liquid return pipe being configured to output the cooling water.

In one of the embodiments, the output port and the input port are quick-connect male connectors configured to be connected quick-connect female connectors of each device to be cooled.

In one of the embodiments, the output port and the input port are quick-connect female connectors configured to be connected to quick-connect male connectors of each device to be cooled.

In one of the embodiments, the liquid cooling water separator further includes a first pipe clamp mounted at a joint between the liquid inlet pipe and the liquid inlet connecting pipe and a second pipe clamp mounted at a joint between the liquid return pipe and the liquid return connecting pipe.

In one of the embodiments, the liquid inlet main body and the liquid return main body are spaced apart in a vertical direction, the liquid inlet main body is higher than the liquid return main body, and the liquid cooling water separator further includes an exhaust valve provided on a top surface of the liquid inlet main body.

In one of the embodiments, two first mounting brackets are provided on two sides of the liquid inlet main body, respectively, the two first mounting brackets are configured to connect the liquid inlet main body to a cabinet, two second mounting brackets are provided on two sides of the liquid return main body, respectively, and the two second mounting brackets are configured to connect the liquid return main body to the cabinet.

In one of the embodiments, the first mounting bracket is provided with a first groove and a first through hole, a first positioning pin is engaged in the first groove, a first fastener extends through the first through hole to connect the first mounting bracket to the cabinet, the second mounting bracket is provided with a second groove and a second through hole, a second positioning pin is engaged in the second groove, and a second fastener extends through the second through hole to connect the second mounting bracket to the cabinet.

In one of the embodiments, a joint between the liquid inlet main body and the liquid inlet connecting pipe is located in a middle position of the liquid inlet main body, and a joint between the liquid return main body and the liquid return connecting pipe is located in a middle position of the liquid return main body.

According to a second aspect, a liquid cooling device for servers is provided, including a cabinet, a cold liquid distribution assembly, and the aforementioned liquid cooling water separator, the cabinet is provided with an accommodating cavity, the accommodating cavity is configured to accommodate a plurality of servers that are placed vertically, the cold liquid distribution assembly is mounted in the cabinet, the output ports of the liquid cooling water separator are connected to liquid inlet ports of the plurality of servers in one-to-one correspondence, the input ports of the liquid cooling water separator are connected to liquid outlet ports of the plurality of servers in one-to-one correspondence, the liquid inlet pipe of the liquid cooling water separator is connected to an output opening of the cold liquid distribution assembly, and the liquid return pipe of the liquid cooling water separator is connected to an input opening of the cold liquid distribution assembly.

In one of the embodiments, an inner side wall of the cabinet is provided with a first mounting hole and a second mounting hole, the liquid cooling water separator is provided with a first through hole and a second through hole, a first fastener extends through the first through hole and is fixed in the first mounting hole, and a second fastener extends through the second through hole and is fixed in the second mounting hole.

In one of the embodiments, an inner side wall of the cabinet is further provided with a first positioning pin and a second positioning pin, the liquid cooling water separator is provided with a first groove and a second groove, the first positioning pin is engaged in the first groove, and the second positioning pin is engaged in the second groove.

According to the aforementioned liquid cooling water separator and aforementioned liquid cooling device, the liquid inlet main body and the liquid return main body are arranged transversely, the liquid inlet main body is connected to the liquid inlet pipe through the liquid inlet connecting pipe, the liquid return main body is connected to the liquid return pipe through the liquid return connecting pipe, and the output ports of the liquid inlet main body are arranged transversely. The output ports are connected to the liquid inlet ports of the devices to be cooled arranged transversely in one-to-one correspondence, the input ports of the liquid return main body are also arranged transversely, and the input ports are connected to the liquid outlet ports of the devices to be cooled arranged transversely in one-to-one correspondence, so that the liquid cooling water separator can be connected to each device to be cooled to form a circuit. Since the liquid inlet main body and the liquid return main body are arranged transversely, the output ports and the input ports are also arranged transversely, and the output ports and the input ports can be directly connected to the devices to be cooled. Connecting pipes are not required to respectively connect the servers to the output ports and the input ports, the mounting processes are simplified, the water leakage hazard of the connecting pipes is reduced, and the liquid cooling water separator has the advantages of convenient use and less safety hazard.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is a perspective view of a liquid cooling water separator according to an embodiment.

FIG. 2 is a rear view of the liquid cooling water separator of FIG. 1.

FIG. 3 is a perspective view of a liquid cooling device for servers according to an embodiment.

FIG. 4 is a front view of the liquid cooling device of FIG. 3.

FIG. 5 is a partial exploded view of the liquid cooling device of FIG. 4.

### DESCRIPTION OF REFERENCE NUMERALS

10. Cabinet; 10A. Accommodating cavity; 11. First mounting hole; 12. Second mounting hole; 13. First positioning pin; 14. Second positioning pin; 20. Cold liquid distribution assembly; 30. Liquid cooling water separator;

100. Liquid inlet main body; 110. Output port; 120. Liquid inlet connecting pipe; 130. First mounting bracket; 130A. First groove; 130B. First through hole;

200. Liquid return main body; 210. Input port; 220. Liquid return connecting pipe; 230. Second mounting bracket; 230A. Second groove; 230B. Second through hole;

300. Liquid inlet pipe; 310. First pipe clamp;

400. Liquid return pipe; 410. Second pipe clamp;

500. Exhaust valve.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “mounted on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

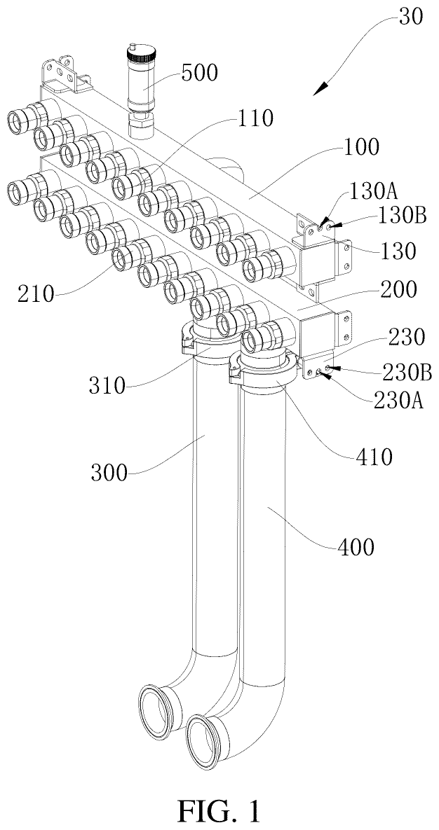

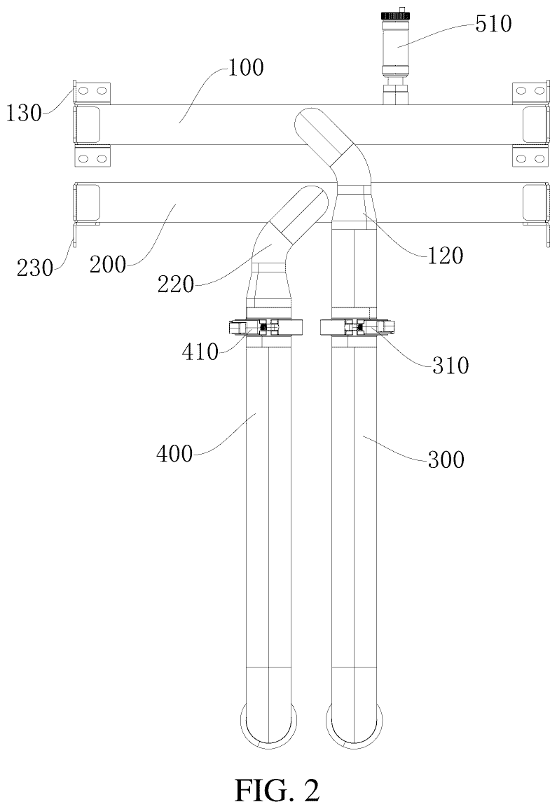

Referring to FIG. 1 and FIG. 2, according to an embodiment, a liquid cooling water separator is provided. The liquid cooling water separator includes a liquid inlet main body 100, a liquid return main body 200, a liquid inlet pipe 300, and a liquid return pipe 400. The liquid inlet main body 100 is arranged transversely. A plurality of output ports 110 are provided on one side of the liquid inlet main body 100, and a liquid inlet connecting pipe 120 is provided on the other side of the liquid inlet main body 100. The liquid inlet connecting pipe 120 is in communication with the plurality of output ports 110, and the output ports 110 are configured to be connected to liquid inlet ports devices to be cooled. The liquid return main body 200 is arranged transversely. A plurality of input ports 210 are provided on one side of the liquid return main body 200, and a liquid return connecting pipe 220 is provided on the other side of the liquid return main body 200. The liquid return connecting pipe 220 is in communication with the plurality of input ports 210, and the input ports 210 are configured to be connected to liquid outlet ports of the devices to be cooled. An output end of the liquid inlet pipe 300 is connected to the liquid inlet connecting pipe 120, and an input end of the liquid inlet pipe 300 is configured to be input with cooling water. An input end of the liquid return pipe 400 is connected to the liquid return connecting pipe 220, and an output end of the liquid return pipe 400 is configured to output the cooling water.

Specifically, the liquid inlet main body 100 and the liquid return main body 200 are cuboid. The liquid inlet main body 100 and the liquid return main body 200 are arranged transversely, in other words, length directions of the liquid inlet main body 100 and the liquid return main body 200 are in the horizontal direction. The liquid inlet main body 100 and the liquid return main body 200 are made of stainless steel, which has advantages such as high strength, strong impact resistance, and long service life.

According to the aforementioned liquid cooling water separator, the liquid inlet main body 100 and the liquid return main body 200 are arranged transversely, the liquid inlet main body 100 is connected to the liquid inlet pipe 300 through the liquid inlet connecting pipe 120, the liquid return main body 200 is connected to the liquid return pipe 400 through the liquid return connecting pipe 220, and the output ports 110 of the liquid inlet main body 100 are arranged transversely. The output ports 110 are connected to the liquid inlet ports of the devices to be cooled arranged transversely in one-to-one correspondence, the input ports 210 of the liquid return main body 200 are also arranged transversely, and the input ports 210 are connected to the liquid outlet ports of the devices to be cooled arranged transversely in one-to-one correspondence, so that the liquid cooling water separator 30 can be connected to each device to be cooled to form a circuit. When the devices to be cooled is cooled, the cooling water is input into the input end of the liquid inlet pipe 300, and the cooling water is delivered to the liquid inlet main body 100 through the liquid inlet connecting pipe 120. The liquid inlet main body 100 then outputs the cooling water to different devices to be cooled through the output ports 110. After heat exchange in the devices to be cooled is completed, the cooling water is delivered back to the liquid return main body 200 through the input ports 210, and then is delivered to the liquid return pipe 400 through the liquid return connecting pipe 220. The output end of the liquid return pipe 400 outputs the cooling water after the heat exchange.

It should be noted that, during use, the cooling water may be input from the output end of the liquid return pipe 400 according to an actual situation, and then injected into different devices to be cooled through the input ports 210 of the liquid return main body 200. After the heat exchange in the devices to be cooled is completed, the cooling water is delivered back to the liquid inlet main body 100 through the output ports 110, and then the cooling water after the heat exchange is output through the input end of the liquid inlet pipe 300. A flow direction of the cooling water in the liquid cooling water separator is not specifically limited.

According to the aforementioned liquid cooling water separator, the liquid inlet main body 100 and the liquid return main body 200 are arranged transversely, so that the output ports 110 and the input ports 210 are also arranged transversely, and the output ports 110 and the input ports 210 can be directly connected to the devices to be cooled. Connecting pipes are not required to respectively connect the devices to be cooled to the output ports 110 and the input ports 210, the mounting processes are simplified, the water leakage hazard of the connecting pipes is reduced, and the liquid cooling water separator has the advantages of convenient use and less safety hazard.

In an optional embodiment, as shown in FIG. 1, the output port 110 and the input port 210 are quick-connect male connectors configured to be connected quick-connect female connectors of each device to be cooled. In other embodiments, the output port 110 and the input port 210 may be quick-connect female connectors configured to be connected to quick-connect male connectors of each device to be cooled. As both the output port 110 and the input port 210 are configured as quick-connect male connectors or quick-connect female connectors, the liquid inlet port and the liquid outlet port of each device to be cooled are correspondingly configured as quick-connect female connectors or quick-connect male connectors, so that the liquid cooling water separator 30 and each device to be cooled can be quickly connected. Moreover, the assembly and disassembly of the liquid cooling water separator 30 and each device to be cooled are simple and can be completed by one hand without additional tools, which has the advantages of convenient and quick disassembly and assembly.

In an optional embodiment, as shown in FIG. 1 and FIG. 2, the liquid cooling water separator 30 further includes a first pipe clamp 310 and a second pipe clamp 410. The first pipe clamp 310 is mounted at a joint between the liquid inlet pipe 300 and the liquid inlet connecting pipe 120. The second pipe clamp 410 is mounted at a joint between the liquid return pipe 400 and the liquid return connecting pipe 220. Specifically, the liquid inlet connecting pipe 120 and the liquid return connecting pipe 220 are made of hard materials, the liquid inlet pipe 300 and the liquid return pipe 400 are flexible pipes, and lengths of the liquid inlet pipe 300 and the liquid return pipe 400 can be flexibly adjusted according to actual positions. The first pipe clamp 310 and the second pipe clamp 410 are hydraulic pipe clamps. The first pipe clamp 310 can lock the liquid inlet pipe 300 and the liquid inlet connecting pipe 120, and the second pipe clamp 410 can lock the liquid return pipe 400 and the liquid return connecting pipe 220, so that the cooling water is delivered to the liquid inlet main body 100 through the liquid inlet pipe 300, and the cooling water in the liquid return main body 200 is output through the liquid return pipe 400, thereby avoiding leakage of the cooling water and improving the stability and flexibility of the liquid cooling water separator 300.

In an optional embodiment, as shown in FIG. 1 and FIG. 2, the liquid inlet main body 100 and the liquid return main body 200 are spaced apart in a vertical direction, and the liquid inlet main body 100 is higher than the liquid return main body 200. The liquid cooling water separator 30 further includes an exhaust valve 500 provided on a top surface of the liquid inlet main body 100. Specifically, the liquid inlet main body 100 and the liquid return main body 200 are provided on the same vertical plane, and the liquid inlet main body 100 is provided directly above the liquid return main body 200. If there is air in the liquid cooling water separator 30, the air will accumulate at the highest position of the whole liquid cooling water separator 30, that is, the top surface of the liquid inlet main body 100. By arranging the exhaust valve 500 on the top surface of the liquid inlet main body 100, the exhaust valve 500 can discharge the air in the liquid cooling water separator 30 and can relieve pressure at the same time, so as to improve the stability of the liquid cooling water separator 30.

In an optional embodiment, as shown in FIG. 1 and FIG. 2, two first mounting brackets 130 are provided on two sides of the liquid inlet main body 100, respectively. The two first mounting brackets 130 are configured to connect the liquid inlet main body 100 to a cabinet 10. Two second mounting brackets 230 are provided on two sides of the liquid return main body 200, respectively. The two second mounting brackets 230 are configured to connect the liquid return main body 200 to the cabinet 10. The first mounting bracket 130 and the second mounting bracket 230 are provided, so that the liquid inlet main body 100 can be fixedly mounted in the cabinet 10 through the first mounting bracket 130, and the liquid return main body 200 can be fixedly mounted in the cabinet 10 through the second mounting bracket 230, which is convenient for disassemble and assemble.

In an optional embodiment, as shown in FIG. 1, the first mounting bracket 130 is provided with a first groove 130A and a first through hole 130B. A first positioning pin 13 is engaged in the first groove 130A. A first fastener extends through the first through hole 130B to connect the first mounting bracket 130 to the cabinet 10. The second mounting bracket 230 is provided with a second groove 230A and a second through hole 230B. A second positioning pin 14 is engaged in the second groove 230A. A second fastener extends through the second through hole 230B to connect the second mounting bracket 230 to the cabinet 10. The first groove 130A and the second groove 230A are provided to cooperate with the positioning pins 13, 14 on the cabinet 10 for mounting, so that the liquid inlet main body 100 and the liquid return main body 200 are preliminarily positioned before mounting, and then the liquid inlet main body 100 is mounted using the first fastener, and the liquid return main body 200 is mounted using the second fastener. The mounting efficiency of the liquid cooling water separator 30 can be improved by the preliminary positioning.

In an alternative embodiment, as shown in FIG. 2, a joint between the liquid inlet main body 100 and the liquid inlet connecting pipe 120 is located in a middle position of the liquid inlet main body 100. A joint between the liquid return main body 200 and the liquid return connecting pipe 220 is located in a middle position of the liquid return main body 200. Specifically, the liquid inlet connecting pipe 120 and the liquid return connecting pipe 220 respectively extend from the middle position thereof toward opposite sides, so as to avoid interference. By arranging an input position of the liquid inlet connecting pipe 120 at the middle position of the liquid inlet main body 100, and arranging an input position of the liquid return connecting pipe 220 at the middle position of the liquid return main body 200, it is beneficial for the cooling water in the liquid inlet connecting pipe 120 to flow evenly into the liquid inlet main body 100, and it is beneficial for the cooling water in the liquid return body 200 to flow evenly into the liquid return connecting pipe 220, thereby improving the stability of the liquid cooling water separator 30.

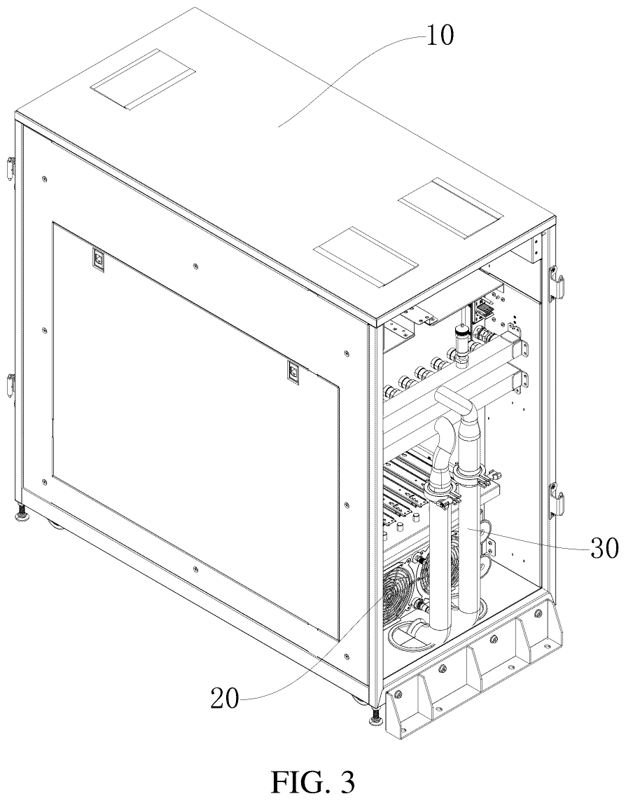

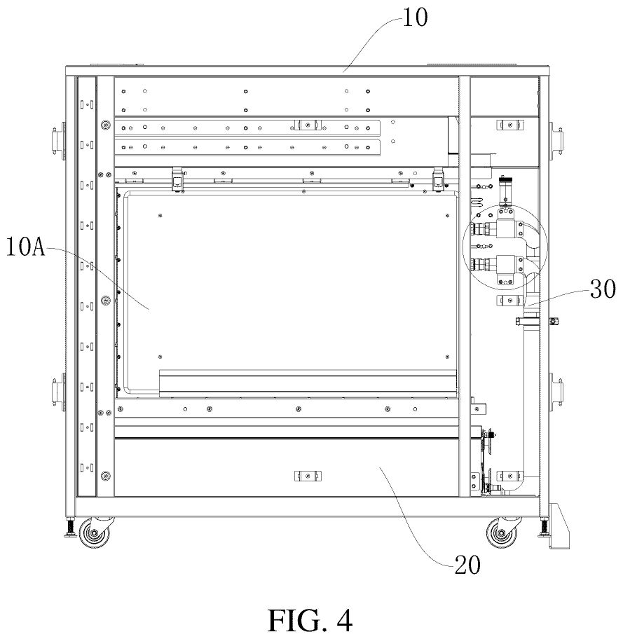

Referring to FIG. 3 and FIG. 4, according to an embodiment, a liquid cooling device for servers is further provided. The liquid cooling device includes a cabinet 10, a cold liquid distribution assembly 20, and the liquid cooling water separator 30 according to any one of the above embodiments. The cabinet 10 is provided with an accommodating cavity 10A, and the accommodating cavity 10A is configured to accommodate a plurality of servers that are placed vertically. The cold liquid distribution assembly 20 is mounted in the cabinet 10. The output ports 110 of the liquid cooling water separator 30 are connected to the liquid inlet ports of the plurality of servers in one-to-one correspondence, the input ports 210 of the liquid cooling water separator 30 are connected to the liquid outlet ports of the plurality of servers in one-to-one correspondence. The liquid inlet pipe 300 of the liquid cooling water separator 30 is connected to an output opening of the cold liquid distribution assembly 20, and the liquid return pipe 400 of the liquid cooling water separator 30 is connected to an input opening of the cold liquid distribution assembly 20.

According to the aforementioned liquid cooling device, the cold liquid distribution assembly 20 is mounted in the cabinet 10, and the servers are placed vertically in the accommodating cavity. Each server and the cold liquid distribution assembly 20 are connected using the liquid cooling water separator 30, and the cold liquid distribution assembly 20 supplies cooling water to the servers, so that the servers can be cooled. Since the liquid inlet main body 100 and the liquid return main body 200 of the liquid cooling water separator 30 are arranged transversely, the output ports 110 and the input ports 210 are also arranged transversely, and the output ports 110 and the input ports 210 can be directly connected to the servers. Connecting pipes are not required to respectively connect the servers to the output ports 110 and the input ports 210, the mounting processes are simplified, the water leakage hazard of the connecting pipes is reduced, and the liquid cooling water separator has the advantages of convenient use and less safety hazard.

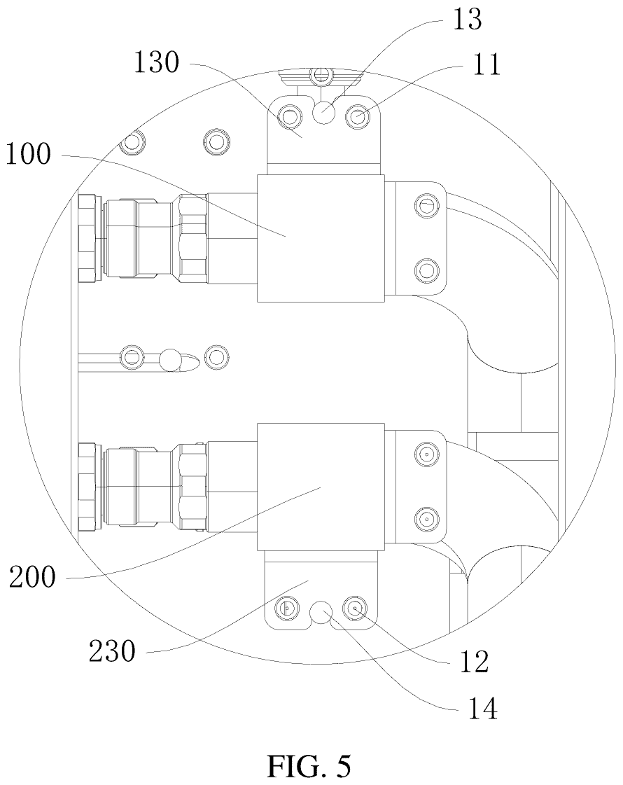

In an optional embodiment, as shown in FIG. 5, an inner side wall of the cabinet 10 is provided with a first mounting hole 11 and a second mounting hole 12. The first fastener extends through the first through hole 130B of the liquid cooling water separator 30 and is fixed in the first mounting hole 11, and the second fastener extends through the second through hole 230B of the liquid cooling water separator 30 and is fixed in the second mounting hole 12. By providing the first mounting hole 11 and the second mounting hole 12 on the inner side wall of the cabinet 10, the liquid inlet main body 100 of the liquid cooling water separator 30 is mounted to the first mounting hole 11, and the liquid return main body 200 is mounted to the second mounting hole 12, so as to fix the liquid cooling water separator 30.

In an optional embodiment, as shown in FIG. 5, the inner side wall of the cabinet 10 is further provided with a first positioning pin 13 and a second positioning pin 14. The first positioning pin 13 is engaged in the first groove 130A of the liquid cooling water separator 30, and the second positioning pin 14 is engaged in the second groove 230A of the liquid cooling water separator 30. By providing the first positioning pin 13 and the second positioning pin 14 on the inner side wall of the cabinet 10, the liquid inlet main body 100 of the liquid cooling water separator 30 is conveniently preliminarily positioned through the first positioning pin 13 when being mounted, and the liquid return main body 200 is conveniently preliminarily positioned through the second positioning pin 14 when being mounted, which has the advantage of convenient mounting.

The liquid cooling water separator and the liquid cooling device for servers described in the embodiments of the present application have the following beneficial effects:

1. The liquid inlet main body 100 and the liquid return main body 200 of the liquid cooling water separator 30 are arranged transversely, so that the output ports 110 and the input ports 210 are also arranged transversely, and the output ports 110 and the input ports 210 can be directly connected to the servers. Connecting pipes are not required to respectively connect the servers to the output ports 110 and the input ports 210, the mounting steps are reduced, the water leakage hazard of the connecting pipes is reduced, and the liquid cooling water separator has the advantages of convenient use and less safety hazard.

2. The input position of the liquid inlet connecting pipe 120 is located at the middle position of the liquid inlet main body 100, and the input position of the liquid return connecting pipe 220 is located at the middle position of the liquid return main body 200. It is beneficial for the cooling water in the liquid inlet connecting pipe 120 to flow evenly into the liquid inlet main body 100, and it is beneficial for the cooling water in the liquid return body 200 to flow evenly into the liquid return connecting pipe 220, thereby improving the stability of the liquid cooling water separator 30.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. A liquid cooling water separator, comprising:
a liquid inlet main body arranged transversely, wherein a plurality of output ports are provided on one side of the liquid inlet main body, a liquid inlet connecting pipe is provided on another side of the liquid inlet main body, the liquid inlet connecting pipe is in communication with the plurality of output ports, and the output ports are configured to be connected to liquid inlet ports of devices to be cooled;
a liquid return main body arranged transversely, wherein a plurality of input ports are provided on one side of the liquid return main body, a liquid return connecting pipe is provided on another side of the liquid return main body, the liquid return connecting pipe is in communication with the plurality of input ports, and the input ports are configured to be connected to liquid outlet ports of the devices to be cooled;
a liquid inlet pipe, an output end of the liquid inlet pipe being connected to the liquid inlet connecting pipe, and an input end of the liquid inlet pipe being configured to be input with cooling water; and
a liquid return pipe, an input end of the liquid return pipe being connected to the liquid return connecting pipe, and an output end of the liquid return pipe being configured to output the cooling water.

2. The liquid cooling water separator according to claim 1, wherein the output port and the input port are quick-connect male connectors configured to be connected quick-connect female connectors of each device to be cooled.

3. The liquid cooling water separator according to claim 1, wherein the output port and the input port are quick-connect female connectors configured to be connected to quick-connect male connectors of each device to be cooled.

4. The liquid cooling water separator according to claim 1, further comprising:
a first pipe clamp mounted at a joint between the liquid inlet pipe and the liquid inlet connecting pipe; and
a second pipe clamp mounted at a joint between the liquid return pipe and the liquid return connecting pipe.

5. The liquid cooling water separator according to claim 1, wherein the liquid inlet main body and the liquid return main body are spaced apart in a vertical direction, the liquid inlet main body is higher than the liquid return main body, and the liquid cooling water separator further comprises an exhaust valve provided on a top surface of the liquid inlet main body.

6. The liquid cooling water separator according to claim 1, wherein two first mounting brackets are provided on two sides of the liquid inlet main body, respectively, the two first mounting brackets are configured to connect the liquid inlet main body to a cabinet, two second mounting brackets are provided on two sides of the liquid return main body, respectively, and the two second mounting brackets are configured to connect the liquid return main body to the cabinet.

7. The liquid cooling water separator according to claim 6, wherein the first mounting bracket is provided with a first groove and a first through hole, a first positioning pin is engaged in the first groove, a first fastener extends through the first through hole to connect the first mounting bracket to the cabinet, the second mounting bracket is provided with a second groove and a second through hole, a second positioning pin is engaged in the second groove, and a second fastener extends through the second through hole to connect the second mounting bracket to the cabinet.

8. The liquid cooling water separator according to claim 1, wherein a joint between the liquid inlet main body and the liquid inlet connecting pipe is located in a middle position of the liquid inlet main body, and a joint between the liquid return main body and the liquid return connecting pipe is located in a middle position of the liquid return main body.

9. A liquid cooling device for servers, comprising a cabinet, a cold liquid distribution assembly, and the liquid cooling water separator according to claim 1, wherein the cabinet is provided with an accommodating cavity, the accommodating cavity is configured to accommodate a plurality of servers that are placed vertically, the cold liquid distribution assembly is mounted in the cabinet, the output ports of the liquid cooling water separator are connected to liquid inlet ports of the plurality of servers in one-to-one correspondence, the input ports of the liquid cooling water separator are connected to liquid outlet ports of the plurality of servers in one-to-one correspondence, the liquid inlet pipe of the liquid cooling water separator is connected to an output opening of the cold liquid distribution assembly, and the liquid return pipe of the liquid cooling water separator is connected to an input opening of the cold liquid distribution assembly.

10. The liquid cooling device according to claim 9, wherein an inner side wall of the cabinet is provided with a first mounting hole and a second mounting hole, the liquid cooling water separator is provided with a first through hole and a second through hole, a first fastener extends through the first through hole and is fixed in the first mounting hole, and a second fastener extends through the second through hole and is fixed in the second mounting hole.

11. The liquid cooling device according to claim 9, wherein an inner side wall of the cabinet is further provided with a first positioning pin and a second positioning pin, the liquid cooling water separator is provided with a first groove and a second groove, the first positioning pin is engaged in the first groove, and the second positioning pin is engaged in the second groove.
